(19) United States
(12) Patent Application Publication
(10) Pub. No.: US 2012/0011417 A1
(43) Pub. Date: Jan. 12, 2012

(54) PLI N-BIT CORRECTION CIRCUIT, GFP LAYER 2 SYNCHRONIZATION CIRCUIT AND GFP FRAME TRANSFER DEVICE USING IT

(76) Inventor: Tsugio Takahashi, Tokyo (JP)

(21) Appl. No.: 13/138,644

(22) PCT Filed: Mar. 18, 2010
(86) PCT No.: PCT/JP2010/001961

§ 371 Date: Sep. 14, 2011

(30) Foreign Application Priority Data
Mar. 24, 2009 (JP) 2009-072200

(51) Int. Cl. H03M 13/05; G06F 11/10

(52) U.S. Cl. 714/775; 714/E11.032

(57) ABSTRACT

A PLI n-bit correction circuit extracts a core header (PLI) from a GFP frame with a fixed payload length; compares it with a predetermined expectation value for each bit; calculates the number of inconsistent bits therebetween; and outputs the predetermined expectation value, instead of the core header, when the number of inconsistent bits is equal to or less than n (n is a natural number); or directly outputs the core header when the number of inconsistent bits is greater than n. A decision on establishment of GFP Layer 2 synchronization is made based on the output of the PLI n-bit correction circuit, wherein predetermined processing is executed on a payload of a GFP frame dropping its core header when GFP Layer 2 synchronization is established, whilst the payload is not subjected to predetermined processing and discarded in the event of GFP Layer 2 desynchronization.

### TECHNICAL FIELD

The present invention relates to PLI n-bit correction circuits constituting core headers of GFP frames. Additionally, the present application relates GFP Layer 2 synchronization circuits and GFP frame transfer devices using PLI n-bit correction circuits.

The present invention claims priority on Japanese Patent Application No. 2009-72200 filed Mar. 24, 2009, the entire content of which is incorporated herein by reference.

### BACKGROUND ART

Transfer devices utilized in network systems adopt GFP (Generic Framing Procedure), which is a technology for encapsulating variable-length payloads storing various client signals and which is used to carry out error detection or GFP Layer 2 synchronization detection. However, transmission lines suffering from numerous bit errors may frequently cause GFP Layer 2 desynchronization, which makes it difficult to secure an adequate quality of communication circuits.

As shown in FIG. 8, one GFP frame is configured of a four-type (32-bit) core header and a payload area. In the core header of the GFP frame, 2 bytes (16 bits) constitute a PLI (Payload Length Indicator), and remaining 2 bytes constitute a CRC (Cyclic Redundancy Checksum; cHEC) of the PLI. In a reception mode, a CRC error detection is carried out to implement 1-bit error correction on the PLI.

Communication lines having a high error rate may cause PLI errors of two bits or more, which cannot be corrected with 1-bit correction. This case entails a GFP Layer 2 desynchronized state, in which a reception device may discard GFP packets until a next GFP Layer 2 synchronization is established.

Generally speaking, the reception device determines that GFP Layer 2 synchronization is deemed established when consecutively receiving PLI two times in order to prevent erroneous GFP Layer 2 synchronization; hence, in this duration, the reception device may unconditionally discard GFP packets.

Patent Document 1 discloses a technology for reducing a probability of causing a communication link disconnected state, namely “Network, Transmission Device, and Transparent Transfer Method therefor”. When a bit error occurs in a client signal, this technology utilizes a transfer device, which interposes and transfers information for discarding the client signal without using an error code, installed in a network.

### PRIOR ART DOCUMENT

### Patent Document

Patent Document 1: Japanese Patent Application Publication No. 2005-6036

### SUMMARY OF THE INVENTION

### Problem to be Solved by the Invention

Upon detecting a bit error, Patent Document 1 teaches that as information for recognizing discarding of a client signal, for example, a code EPD (End of Packet Delimiter) is interposed at a fault position. This may reduce a probability of causing communication link disconnections but cannot reduce a probability of discarding GPF packets.

The present invention aims to provide a technology for preventing GFP Layer 2 desynchronization and for reducing a probability of discarding GPF packets, and in particular, a PLI n-bit correction circuit, a GFP Layer 2 synchronization circuit and a GFP frame transfer circuit using it.

### Means for Solving the Problem

A PLI n-bit correction circuit of the present invention compares a core header included in a GFP frame of a fixed payload length with a predetermined expectation value per each bit, calculates the number of inconsistent bits therebetween, and outputs the predetermined expectation value instead of the core header when the number of inconsistent bits is equal to or less than n (where n is a natural number).

A GFP Layer 2 synchronization circuit of the present invention includes a core header drop circuit which extracts a core header from a GFP frame of a fixed payload length; a PLI n-bit correction circuit which compares the core header with a predetermined expectation value per each bit, calculates the number of inconsistent bits therebetween, and outputs the predetermined expectation value instead of the core header when the number of inconsistent bits is equal to or less than n (where n is a natural number) or directly outputs the core header when the number of inconsistent bits is greater than n; a Layer 2 synchronization monitor circuit which generates a Layer 2 synchronization signal indicating establishment of Layer 2 synchronization when the PLI n-bit correction circuit consecutively outputs errorless core headers two times or indicating Layer 2 desynchronization when the PLI n-bit correction circuit directly outputs the core header without error correction since the number of inconsistent bits exceeds n; and a selector which supplies the output of the PLI n-bit correction circuit to the Layer 2 synchronization monitor circuit when the Layer 2 synchronization signal indicates establishment of Layer 2 synchronization or which supplies the core header output from the core header drop circuit to the Layer 2 synchronization monitor circuit when the Layer 2 synchronization signal indicates Layer 2 desynchronization.

A GFP frame transfer circuit of the present invention includes a receiver which receives a GFP frame of a fixed payload length; a core header drop circuit which extracts a core header from the GFP frame; a PLI n-bit correction circuit which compares the core header with a predetermined expectation value per each bit, calculates the number of inconsistent bits therebetween, and outputs the predetermined expectation value instead of the core header when the number of inconsistent bits is equal to or less than n (where n is a natural number) or directly outputs the core header when the number of inconsistent bits is greater than n; a Layer 2 synchronization monitor circuit which generates a Layer 2 synchronization signal indicating establishment of Layer 2 synchronization when the PLI n-bit correction circuit consecutively outputs errorless core headers two times or indicating Layer 2 desynchronization when the PLI n-bit correction circuit directly outputs the core header without error correction since the number of inconsistent bits exceeds n; a selector which supplies the output of the PLI n-bit correction circuit to the Layer 2 synchronization monitor circuit when the Layer 2 synchronization signal indicates establishment of Layer 2 synchronization or which supplies the core header output from the core header drop circuit to the Layer 2 synchronization monitor circuit when the Layer 2 synchronization signal indicates Layer 2 desynchronization; and a GFP frame processing circuit which performs a predetermined process on the payload of the GFP frame dropping the core header when the Layer 2 synchronization signal indicates establishment of Layer 2 synchronization or which discards the GFP frame without performing the predetermined process on the payload when the Layer 2 synchronization signal indicates Layer 2 desynchronization.

A PLI n-bit correction method of the present invention compares a core header included in a GFP frame of a fixed payload length with an predetermined expectation value per each bit, calculates the number of inconsistent bits therebetween, and outputs the predetermined expectation value instead of the core header when the number of inconsistent bits is equal to or less than n (where n is a natural number).

A GFP frame transfer method of the present invention extracts a core header from a GFP frame of a fixed payload length; compares the core header with a predetermined expectation value per each bit; calculates the number of inconsistent bits therebetween; outputs the predetermined expectation value instead of the core header when the number of inconsistent bits is equal to or less than n (where n is a natural number) or directly outputs the core header when the number of inconsistent bits is greater than n; generates a Layer 2 synchronization signal indicating establishment of Layer 2 synchronization when errorless core headers are consecutively output two times or indicating Layer 2 desynchronization when the core header is directly output without error correction since the number of inconsistent bits exceeds n; and performs a predetermined process on the payload of the GFP frame dropping the core header when the Layer 2 synchronization signal indicates establishment of Layer 2 synchronization or discards the GFP frame without performing the predetermined process on the payload when the Layer 2 synchronization signal indicates Layer 2 desynchronization.

### Effect of the Invention

The present invention is characterized in that a GFP Layer 2 synchronization circuit and a GFP frame transfer device are equipped with a PLI n-bit correction circuit which compares the core header (PLI) of a GFP frame with a predetermined expectation value per each bit so that the expectation value is output instead of the core header when the number of inconsistent bits therebetween is equal to or less than n (where n is a natural number). Additionally, the present invention makes a decision as to whether or not GFP Layer 2 is established based on the output of the PLI n-bit correction circuit, wherein a predetermined process is carried out on a payload of a GFP frame, which is then output onto a transmission line when the GFP Layer 2 synchronization is established, whilst the payload is discarded when GFP Layer 2 desynchronization is confirmed. This makes it possible to properly perform error correction on GFP frames; hence, it is possible to prevent GFP Layer 2 desynchronization, and it is possible to reduce the probability of discarding GFP packets.

### BRIEF DESCRIPTION OF THE DRAWINGS

FIG. 1 A block diagram showing the constitution of a GFP Layer 2 synchronization circuit including a PLI n-bit correction circuit according to Embodiment 1 of the present invention.

FIG. 2 A block diagram showing the constitution of the PLI n-bit correction circuit of Embodiment 1.

FIG. 3 A block diagram showing the constitution of a GFP frame transfer device including the PLI n-bit correction circuit and the GFP Layer 2 synchronization circuit according to Embodiment 1.

FIG. 4 A waveform chart used for explaining the operation of the GFP frame transfer device of Embodiment 1.

FIG. 5 A block diagram showing the constitution of a PLI n-bit correction circuit according to Embodiment 2 of the present invention.

FIG. 6 A block diagram showing the constitution of a PLI n-bit correction circuit according to Embodiment 3 of the present invention.

FIG. 7 A block diagram showing the constitution of a PLI n-bit correction circuit according to a variation of Embodiment 3.

FIG. 8 An illustration of the configuration of a GFP frame.

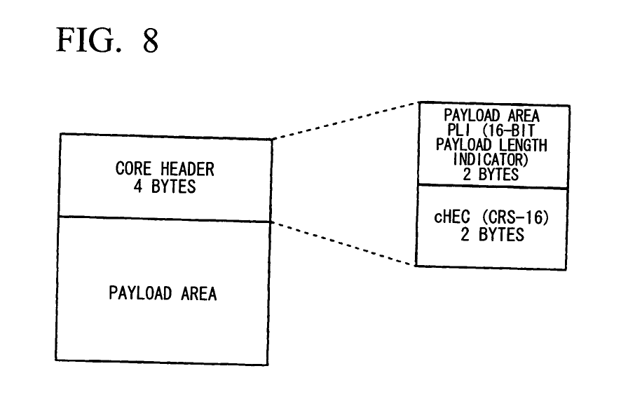

### BEST MODE FOR CARRYING OUT THE INVENTION

The present invention will be described in detail with reference to the accompanying drawings. Hereinafter, a PLI n-bit correction circuit adapted to a GFP frame transfer device and a GFP Layer 2 synchronization circuit will be described in conjunction with embodiments.

### Embodiment 1

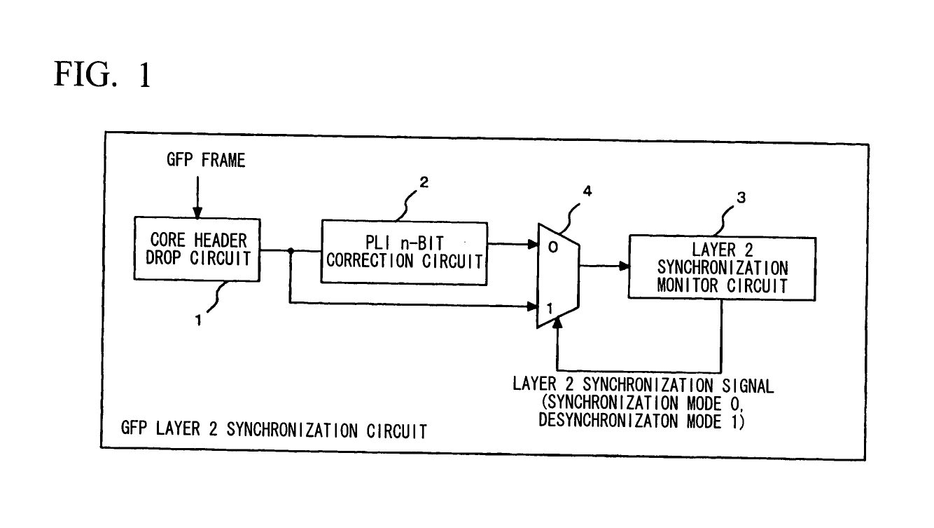

FIG. 1 shows the constitution of a GFP Layer 2 synchronization circuit 10 according to Embodiment 1 of the present invention. The GFP Layer 2 synchronization circuit 10 includes a core header drop circuit 1, a PLI n-bit correction circuit 2, a Layer 2 synchronization monitor circuit 3, and a selector 4. The core header drop circuit 1 extracts core headers from GFP frames received via transmission lines. The PLI n-bit correction circuit 2 compares PLI of each core header with a predetermined expectation value so as to measure the inconsistent number therebetween, wherein when the inconsistent number is equal to or less than n (where n is a natural number), the PLI is regarded as an expectation and replaced with the predetermined expectation value. Since Layer 2 synchronization is monitored without performing bit correction in the event of Layer 2 desynchronization, the selector 4 forwards the PLI to the Layer 2 synchronization monitor circuit 3 without performing bit correction on the PLI. The Layer 2 synchronization monitor circuit 3 supplies a Layer 2 synchronization signal to the selector 4 in such a way that Layer 2 synchronization is established upon consecutively receiving the correct PLI two times, whilst Layer 2 desynchronization is confirmed upon receiving a PLI with the large number of inconsistent bits, between PLI and its expectation, larger than n. In the event of Layer 2 synchronization established, the selector 4 forwards the output signal of the PLI n-bit correction circuit 2 to the Layer 2 synchronization monitor circuit 3. In the event of Layer 2 desynchronization, the selector 4 forwards a PLI of a core header, extracted by the core header drop circuit 1, to the Layer 2 synchronization monitor circuit 3. Thus, a PLI of a core header is directly supplied to the Layer 2 synchronization monitor circuit 3 in the event of Layer 2 desynchronization.

It is possible to carry out bit error correction, not using CRC, on GFP_T frames with a fixed payload length if their expectations are known. Additionally, it is possible to carry out bit error correction, not using CRC, on GFP frames with a variable payload length if they are utilized with a fixed payload length and if their expectations are known. Embodiment 1 carries out bit error correction, not using CRC, in such a way that a PLI is replaced with the expectation value when the PLI, compared with a predetermined expectation value, falls within a bit-error correctable range. The following description refers to “GFP frames with a fixed payload length”, embracing GFP_T frames with a fixed payload length and other GFP frames with a variable payload length which is temporarily fixed to an arbitrary value.

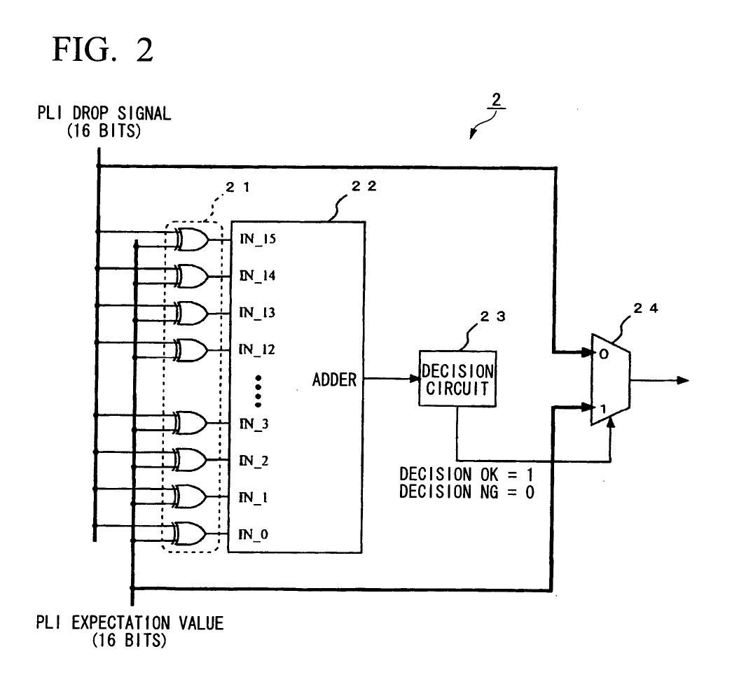

FIG. 2 shows the constitution of a PLI n-bit correction circuit 2 according to Embodiment 1. The PLI n-bit correction circuit 2, which inputs a PLI drop signal (16 bits) and a PLI expectation value (16 bits), includes an EX-OR (Exclusive-OR) 21 for calculating exclusive-OR values therebetween, an adder 22 for adding outputted bits, a decision circuit 23 for making a decision as to whether or not the addition result is equal to or less than a predetermined threshold, and a selector 24 for replacing the PLI with the PLI expectation value when the addition result is equal to or less than the predetermined threshold.

The EX-OR 21 is supplied with bits of PLI included in a core header, which the core header drop circuit 1 extracts from a GFP packet. Additionally, the EX-OR 21 is supplied with bits of the predetermined PLI expectation value. The EX-OR 21 outputs “1” when the PLI matches with the PLI expectation value for each bit, while the EX-OR 21 outputs “0” when they do not match with each other. The adder 22 adds bits output from the EX-OR 21. The addition result of the adder 22 indicates the number of inconsistent bits between the PLI included in the core header and the PLI expectation value. The decision circuit 23 makes a decision as to whether or not error correction can be performed on PLI by way of a decision as to whether or not the addition result is equal to or less than the predetermined threshold. When the addition result is equal to or less than the predetermined threshold, the decision circuit 23 determines that error correction is executable, wherein the decision circuit 23 sets “1” to the selector 24, thus replacing the PLI with the PLI expectation value. In contrast, when the addition result exceeds the predetermined threshold, the decision circuit 23 determines that error correction is not executable, wherein the decision circuit 23 sets “0” to the selector 24, thus directly outputting the PLI without replacing it with the PLI expectation value. In this case, the Layer 2 synchronization monitor circuit 3 detects Layer 2 desynchronization.

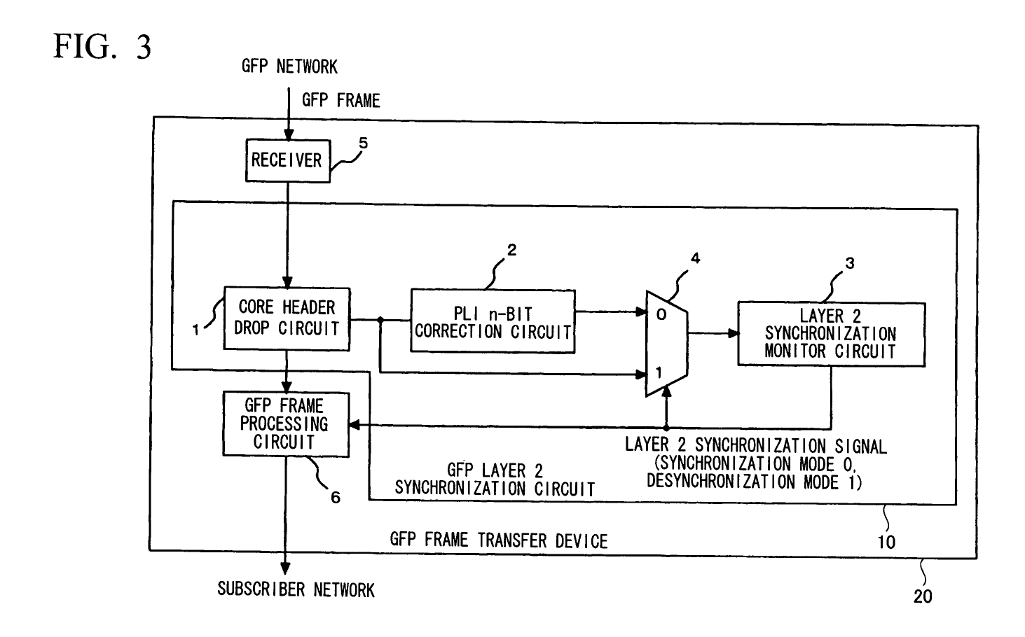

FIG. 3 shows the constitution of a GFP frame transfer device 20 using the GFP Layer 2 synchronization circuit 10 according to Embodiment 1. In addition to the constituent elements of the GFP Layer 2 synchronization circuit 10, the GFP frame transfer device 20 includes a receiver 5 which receives a GFP frame with a fixed payload length transmitted via a transmission line (a GFP network), and a GFP frame processing circuit 6. The GFP frame processing circuit 6 deletes a payload header included in a payload area of a GFP frame with a fixed payload length, from which a core header is dropped by the core header drop circuit 1, so as to generate a user packet, which is added with an overhead and then output to a subscriber network. Herein, the GFP frame processing circuit 6 performs this process when the Layer 2 synchronization monitor circuit 3 supplies a Layer 2 synchronization signal notifying establishment of Layer 2 synchronization. When the Layer 2 synchronization signal notifies Layer 2 desynchronization, the GFP frame processing circuit 6 discards the GFP frame with a fixed payload length without carrying out the above process. This specification does not refer to the details of the processing of the GFP frame processing circuit 6 because it can be arbitrarily determined.

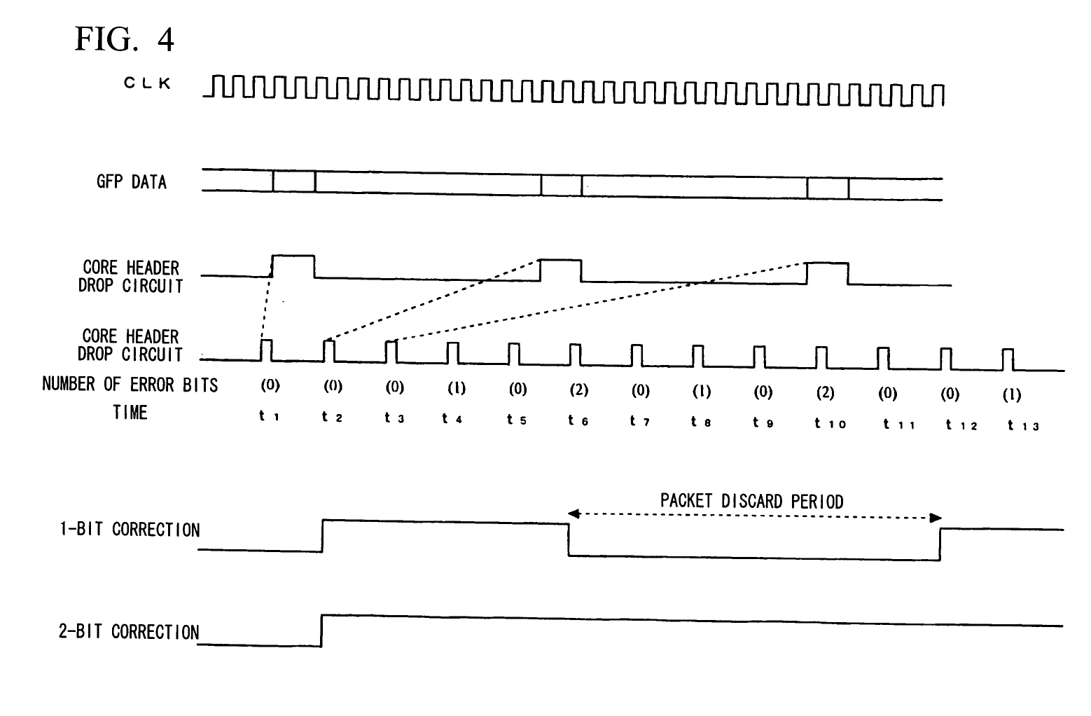

The operation of the GFP frame transfer device 20 when n=2 will be described with reference to a waveform chart of FIG. 4.

First, the operation of the GFP frame transfer device 20 using a 1-bit correction circuit will be described prior to comparison with Embodiment 1 adopting a 2-bit correction circuit. Layer 2 synchronization is established when the number of error bits included in PLI extracted by the core header drop circuit 1 consecutively reads “0” two times at times t1, t2. At subsequent times t3, t4, t5, the number of error bits included in PLI reads “0”, “1”, “0”, indicating one or less error bit, which is corrected by the 1-bit correction circuit so that establishment of Layer 2 synchronization is sustained. At time t6, however, the number of error bits becomes “2”, wherein these error bits are not corrected so that Layer 2 desynchronization occurs. Thereafter, at times t7 to t12, the number of error bits included in PLI reads “0”, “1”, “0”, “2”, “0”, “0”, wherein Layer 2 synchronization is re-established at time t12 when the number of error bits has consecutively read “0” two times. That is, Layer 2 desynchronization is maintained in the period from t6 to t12, in which received packets are all discarded.

The GFP frame transfer device 20 of Embodiment 1, adopting the 2-bit correction circuit, operates similarly with the GFP frame transfer device using the 1-bit correction circuit in the period from time t1 to time t5, wherein Layer 2 synchronization is established at time t2, thereafter, the 2-bit correction circuit corrects error bits so as to maintain the establishment of Layer 2 synchronization. Since the number of error bites included in PLI consecutively reads “2” or less in the period from time t7 to time t12, the 2-bit correction circuit corrects those error bits so as to maintain the establishment of Layer 2 synchronization.

Thus, it is possible to prevent Layer 2 desynchronization because the GFP Layer 2 synchronization circuit 10 of Embodiment 1 is able to correct multiple bits included in each core header. Therefore, the GFP frame transfer device 20 employing the GFP Layer 2 synchronization circuit 10 is able to reduce a probability of discarding packets. Since Layer 2 desynchronization hardly occurs, it is possible to carry out GFP communication via communication lines with a low quality of communication (or a high error rate).

### Embodiment 2

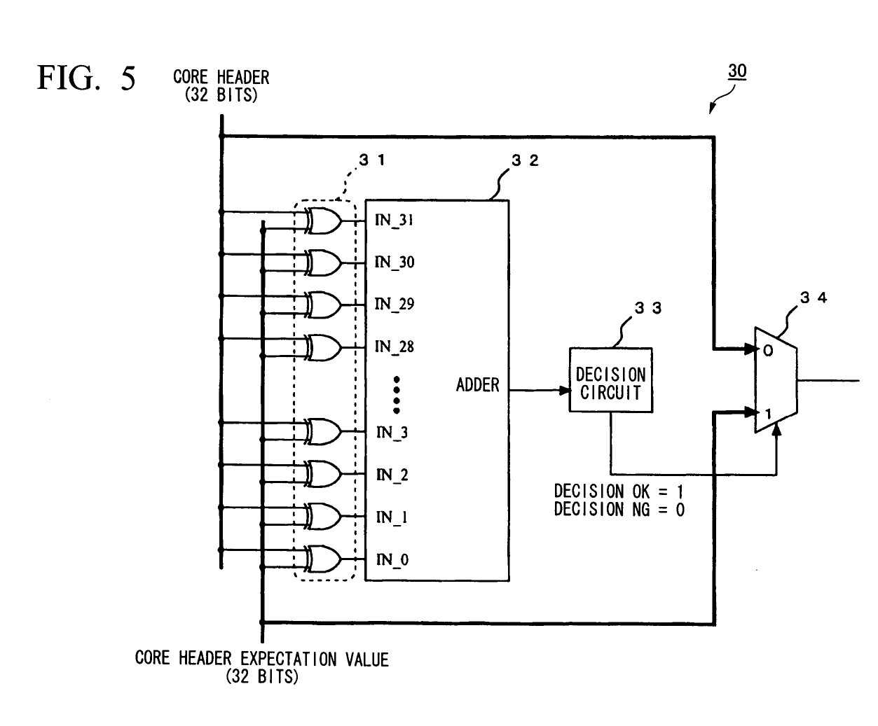

The Embodiment 2 of the present invention will be described. The Embodiment 2 adopts the same GFP Layer 2 synchronization circuit 10 as the Embodiment 1, whereas the PLI n-bit correction circuit 2 is replaced with a PLI n-bit correction circuit 30 shown in FIG. 5. Similar to the Embodiment 1, the Embodiment 2 is adaptable to the GFP frame transfer device 20.

FIG. 5 shows the constitution of the PLI n-bit correction circuit 30 according to Embodiment 2. The PLI n-bit correction circuit 30 is supplied with the entirety of a core header (32 bits) including CRC in addition to PLI from the core header drop circuit 1, so that the PLI expectation value consists of 32 bits. An EX-OR 31 includes thirty-two exclusive-OR circuits (Exclusive OR), the number of which is identical to the bit configuration, whilst an adder 32 adds 32 bits output from the EX-OR 31. A decision circuit 33 makes a decision as to whether or not error correction is executable on PLI of a core header supplied from the core header drop circuit 1 by way of a decision as to whether or not the addition result of the adder 32 is equal to or less than a predetermined threshold. When the addition result is equal to or less than the predetermined threshold, the decision circuit 33 determines that error correction is executable on PLI, wherein the decision circuit 33 sets “1” to a selector 34, thus replacing the PLI with a PLI expectation value included in a predetermined core header expectation value. In contrast, when the addition result exceeds the predetermined threshold, the decision circuit 33 determines that error correction is executable on PLI, wherein the decision circuit 33 sets “0” to the selector 34, thus directly outputting the PLI without replacing it with the PLI expectation value.

Since Embodiment 2 compares the entirety of a core header with the core header expectation value, it is possible to execute error correction on condition that the number of error bits included in the core header is equal to or less than the predetermined value even when a burst error occurs in first sixteen bits (i.e. PLI) of the core header. When 4-bit correction is designated, for example, it is possible to execute error correction on PLI undergoing consecutive four error bits.

When the PLI n-bit correction circuit 2 of Embodiment 1 compares only the PLI with the PLI expectation value so as to carry out 4-bit correction, for example, the correction rates is 4/16=25%, thus increasing a probability of not carrying out error correction due to misreading a true error of PLI as no problem.

When the PLI n-bit correction circuit 30 of Embodiment 2 compares the entirety of a core header with the core header expectation value so as to carry out 4-bit correction, the correction rate is 4/32=12.5%, thus halving a probability, compared to Embodiment 1, in precluding error correction due to misreading a true error of PLI as no problem.

In this connection, Embodiment 2 is identical to Embodiment 1 except for the error correction process; hence, duplicate descriptions will be omitted.

Based on the result of comparison between a core header and a core header expectation value, Embodiment 2 replaces only the PLI, included in the core header, with the core header expectation value, whereas it is possible to reconfigure Embodiment 2 such that the entirety of the core header is replaced with the core header expectation value.

### Embodiment 3

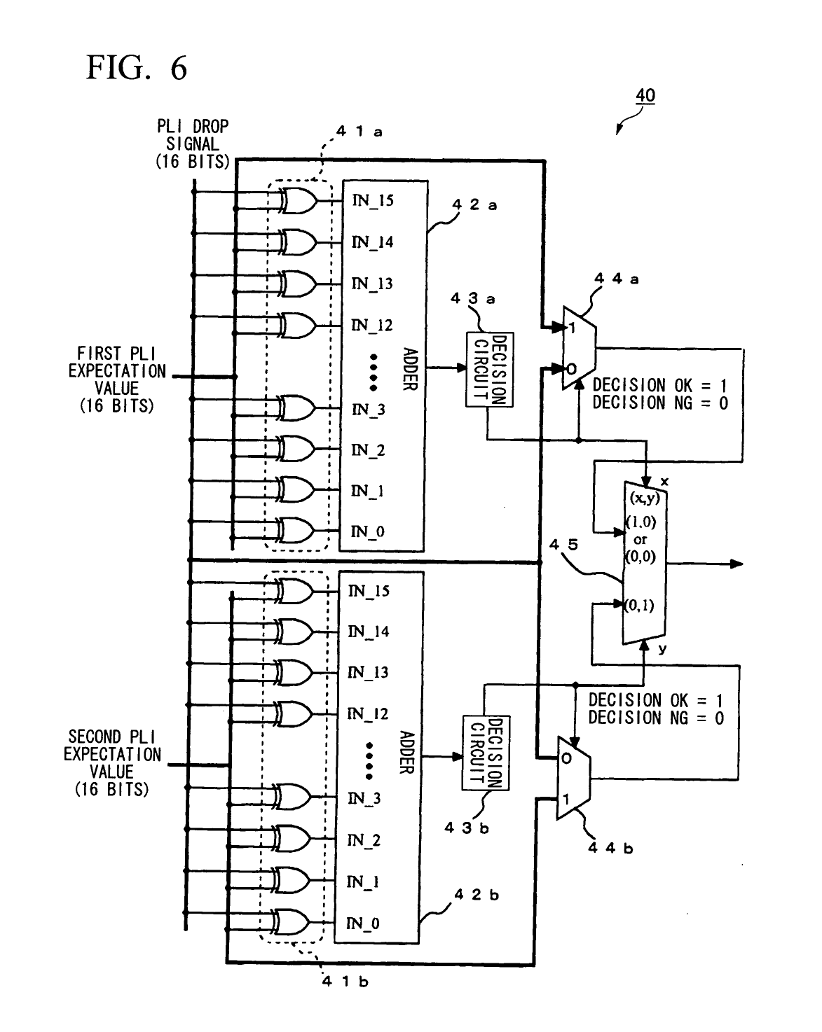

Now, Embodiment 3 will be described. Embodiment 3 employs the same GFP Layer 2 synchronization circuit 10 as Embodiment 1,whereas Embodiment 3 employs a PLI n-bit correction circuit 40 shown in FIG. 6 instead of the PLI n-bit correction circuit 2. Similar to Embodiment 1, Embodiment 3 is applied to the GFP frame transfer device 20.

FIG. 6 shows the constitution of a PLI n-bit correction circuit 40 according to Embodiment 3. The PLI n-bit correction circuit 40 of Embodiment 3 uses two types of PLI expectation values; hence, Embodiment 3 includes two systems as the constitution of the PLI n-bit correction circuit 2 of Embodiment 1. In a first system, an EX-OR 41a compares a PLI, supplied from the core header drop circuit 1, with a first PLI expectation value for each bit, so that the comparison result thereof is supplied to an adder 42a. The adder 42a adds bits output from the EX-OR 41a. A decision circuit 43a makes a decision as to whether or not error correction is executable on the PLI of a core header by way of a decision as to whether or not the addition result of the adder 42a is equal to or less than a predetermined threshold. When the addition result is equal to or less than the predetermined threshold, the decision circuit 43a determines that error correction is executable on the PLI, so that the decision circuit 43a sets “1” to a selector 44a, thus replacing the PLI with the PLI expectation value. In contrast, when the addition result exceeds the predetermined threshold, the decision circuit 43a determines that error correction is not executable on the PLI, so that the decision circuit 43a sets “0” to the selector 44a, thus directly outputting the PLI without replacing it with the PLI expectation value.

A second system includes an EX-OR 41b, an adder 42b, a decision circuit 43b, and a selector 44b so as to carry out the same processing, described above, using a second PLI expectation value.

The decision results of the decision circuits 43a, 43b are forwarded to a selector 45. The selector 45 inputs the decision result “x” of the decision circuit 43a and the decision result “y” of the decision circuit 43b, thus switching the output thereof based on their combination (x,Y). That is, when one of the decision results of the decision circuits 43a, 43b is “OK” whilst the other is “NG”, the selected PLI expectation value (i.e. the first PLI expectation value or the second PLI expectation value), which is output from the selector 44a or the selector 44b indicating the decision result of OK, is output from the selector 45. When both the decision circuits 43a, 43b indicate the decision result of NG, both the selectors 44a, 44b directly output the PLI included in a core header without replacing it with their PLI expectation values. In this case, the selector 45 selectively outputs the PLI output from the selector 44a. FIG. 6 shows that the selector 45 selects the output of the selector 44a based on the combination (0,0) of decision results; instead, it is possible to select the output of the selector 44b.

The situation in which both the decision results of the decision circuits 43a, 43b are OK may indicate a probability that the PLI is replaced with a wrong PLI expectation value. To prevent this situation, the decision circuits 43a, 43b are bound by the condition that when the number of inconsistent bits, between two PLI expectation values which are compared with each other for each bit, is equal to or less than m (where m is a natural number), error correction can be performed within an allowable range where the number of corrected bits is less than m/2 (i.e. n<m/2). By setting this condition, it is possible to prevent the situation in which both the decision results of the decision circuits 43a, 43b indicate OK. For instance, it is possible to prevent the PLI, which should be replaced with the first PLI expectation value, from being replaced with the second PLI expectation value.

This operation will be described in detail. Two types of frames, i.e. normal frames (CDF: Client Data Frame) and management information transfer frames (CMF: Client Management Frame), are prescribed as GFP_T frames, wherein these frames are each defined with a fixed payload length. Since the entirety of CDF consists of 6,373 bytes while the entirety of CMF consists of 68 bytes, CDF includes a cHEC value configured of 6,369 bytes while CMF includes a cHEC value configured of 64 bytes. That is, it is estimated that PLI may take either 6,369 or 64. In this case, the first PLI expectation value is set to “6,369” (18E1h=0001_{—}1000_{—}1110_{—}0001), whilst the second PLI expectation value is set to “64” (0040h=0000_{—}0000_{—}0100_{—}0000).

Through comparison between the first PLI expectation value and the second PLI expectation value wherein inconsistent bits therebetween are each set to “1”, it is possible to produce “0001_{—}1000_{—}1010_{—}0001”, indicating that the number of inconsistent bits is “5”. This leads to n<m/2=5/2=2.5, indicating a wrong PLI expectation value may not be mistakenly selected if error correction is made within two bits.

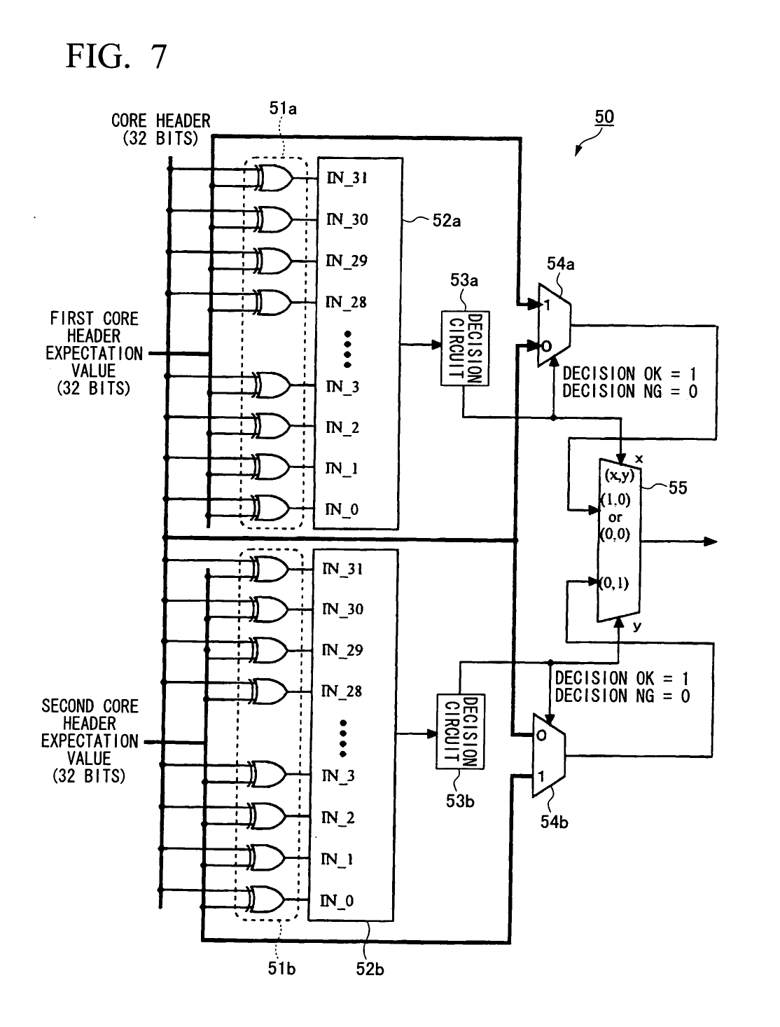

FIG. 7 shows the constitution of a PLI n-bit correction circuit 50 according to a variation of Embodiment 3. Similar to the PLI n-bit correction circuit 30 of Embodiment 2, the PLI n-bit correction circuit 50 according to a variation of Embodiment 3 inputs the entirety of a core header including PLI and CRC (32 bits) so that core header expectation values consist of 32 bits.

The PLI n-bit correction circuit 50 includes two systems, wherein a first system using a first core header expectation value includes an EX-OR 51a, an adder 52a, a decision circuit 53a, and a selector 54a, whilst a second system using a second core header expectation value includes an EX-OR 51b, an adder 52b, a decision circuit 53b, and a selector 54b. The outputs of the selectors 54a, 54b are supplied to a selector 55, which switches its output based on a combination (x,y) of the decision results of the decision circuits 53a, 53b.

For instance, the first core header expectation value is a combination of the first PLI expectation value “6,396 (18E1h)” and CRC “67D5h” of CDF. The second core header expectation value is a combination of the second PLI expectation value “64(0040h)” and CRC “48C4h” of CMF.

That is, the first core header expectation value is “18E167D5h=0001_{—}1000_{—}1110_{—}0001_{—}0110_{—}0111_{—}1101_{—}0101”, whilst the second core header expectation value is “004048C4h=0001_{—}1000_{—}1010_{—}0001_{—}0010_{—}1111_{—}0001_{—}0001”.

Through comparison between the first core header expectation value and the second core header expectation value per each bit wherein inconsistent bits therebetween are each set to “1”, it is possible to produce “0001_{—}1000_{—}1010_{—}0001_{—}0010_{—}1111_{—}0001_{—}0001”, indicating that the number of inconsistent bits is “12”. This leads to n<m/2=12/2=6, indicating that a wrong core header expectation value may not be mistakenly selected if error correction is made within five bits.

Embodiment 3 employs two types of expectation values, but it is possible to use three or more types of expectation values. In this case, a minimum value as to the number of inconsistent bits detected between two expectation values is defined as “m”, wherein error correction is executable if the number of corrected bits falls within an allowable range of n<m/2. Specifically, three types of expectation values a, b, c are classified into three combinations, i.e. a combination of expectation values a-b, a combination of expectation values b-c, and a combination of expectation values c-a, so that three numbers of inconsistent bits, m1, m2, m3, are calculated. When the number m1 of inconsistent bits in the combination of expectation values a-b is “6”, the number m2 of inconsistent bits in the combination of expectation values b-c is “5”, and the number m3 of inconsistent bits in the combination of expectation values c-a is “7”, for example, it is possible to carry out error correction within an allowable range as the number of corrected bits which is less than a half the minimum number m2 of inconsistent bits.

As described above, the GFP Layer 2 synchronization circuit 10 using the PLI n-bit correction circuit 40 or 50 according to Embodiment 3 is able to prevent improper error correction using an inappropriate PLI expectation value which is mistakenly selected. Therefore, Layer 2 desynchronization may hardly occur, and any error may hardly occur in GFP packet processing.

The present invention is not necessarily limited to the foregoing embodiments, which can be further modified in various ways within the scope of the invention defined by the appended claims.

For instance, it is possible to additionally arrange a 1-bit correction circuit in addition to the PLI n-bit correction circuit according to each embodiment, wherein the PLI n-bit correction circuit is allowed to correct multiple bits only when the 1-bit correction circuit is unable to carry out error correction.

### INDUSTRIAL APPLICABILITY

The present invention is designed to carry out error correction on multiple bits (n bits) of PLI included in a core header of a GFP frame in a GFP Layer 2 synchronization circuit and a GFP frame transfer device applied to a network system; hence, the present invention can be applied to various types of network-associated devices and communication devices.

### DESCRIPTION OF THE REFERENCE NUMERALS

1 Core header drop circuit
2 PLI n-bit correction circuit (Embodiment 1)
3 Layer 2 synchronization monitor circuit
4 Selector
5 Receiver
6 GFP frame processing circuit
10 GFP Layer 2 synchronization circuit
20 GFP frame transfer device
20 PLI n-bit correction circuit (Embodiment 2)
40 PLI n-bit correction circuit (Embodiment 3)
50 PLI n-bit correction circuit (variation of Embodiment 3)

1. A PLI n-bit correction circuit which compares a core header, included in a GFP frame with a fixed payload length, with a predetermined expectation value for each bit so as to calculates the number of inconsistent bits therebetween and which outputs the predetermined expectation value instead of the core header when the number of inconsistent bits is equal to or less than n (where n is a natural number).

2. The PLI n-bit correction circuit according to claim 1, wherein the core header is directly output when the number of inconsistent bits is greater than n.

3. The PLI n-bit correction circuit according to claim 1, wherein a PLI included in the core header is compared with a PLI expectation value, thus calculating the number of inconsistent bits therebetween.

4. The PLI n-bit correction circuit according to claim 1, wherein the core header and the predetermined expectation value are subjected to exclusive-OR operation for each bit and then added together, thus calculating the number of inconsistent bits therebetween.

5. The PLI n-bit correction circuit according to claim 1, wherein a first expectation value and a second expectation value are used as the predetermined expectation value, wherein a first number of inconsistent bits is calculated based on the first expectation value whilst a second number of inconsistent bits is calculated based on the second expectation value, and wherein the minimum number of inconsistent bits, which is either the first or second number of inconsistent bits, is defined as m, which satisfies a condition of n<m/2.

6. A GFP Layer 2 synchronization circuit comprising:
a core header drop circuit which extracts a core header from a GFP frame with a fixed payload length;
a PLI n-bit correction circuit which compares the core header with a predetermined expectation value per each bit so as to calculate the number of inconsistent bits therebetween, which outputs the predetermined expectation value instead of the core header when the number of inconsistent bits is equal to or less than n (where n is a natural number), or which directly outputs the core header when the number of inconsistent bits is greater than n;
a Layer 2 synchronization monitor circuit which generates a Layer 2 synchronization signal indicating establishment of Layer 2 synchronization when the PLI n-bit correction circuit consecutively outputs errorless core headers two times or an event of Layer 2 desynchronization when the number of inconsistent bits exceeds n so that the PLI n-bit correction circuit directly outputs the core header without error correction; and
a selector which supplies the Layer 2 synchronization monitor circuit with the output of the PLI n-bit correction circuit when the Layer 2 synchronization signal indicates establishment of Layer 2 synchronization or which supplies the Layer 2 synchronization monitor circuit with the core header output from the core header drop circuit when the Layer 2 synchronization signal indicates the event of Layer 2 desynchronization.

7. A GFP frame transfer device comprising:
a receiver which receives a GFP frame with a fixed payload length;
a core header drop circuit which extracts a core header from the GFP frame;
a PLI n-bit correction circuit which compares the core header with a predetermined expectation value per each bit so as to calculate the number of inconsistent bits therebetween, which outputs the predetermined expectation value instead of the core header when the number of inconsistent bits is equal to or less than n (where n is a natural number), or which directly outputs the core header when the number of inconsistent bits is greater than n;
a Layer 2 synchronization monitor circuit which generates a Layer 2 synchronization signal indicating establishment of Layer 2 synchronization when the PLI n-bit correction circuit consecutively outputs errorless core headers two times or an event of Layer 2 desynchronization when the PLI n-bit correction circuit directly outputs the core header without error correction;
a selector which supplies the Layer 2 synchronization monitor circuit with the output of the PLI n-bit correction circuit when the Layer 2 synchronization signal indicates establishment of Layer 2 synchronization or which supplies the Layer 2 synchronization monitor circuit with the core header output from the core header drop circuit when the Layer 2 synchronization signal indicates the event of Layer 2 desynchronization; and
a GFP frame processing circuit which executes predetermined processing on a payload of the GFP frame dropping the core header when the Layer 2 synchronization signal indicates establishment of Layer 2 synchronization or which discards the GPF frame without performing the predetermined processing on the payload when the Layer 2 synchronization signal indicates the event of Layer 2 desynchronization.

8. A PLI n-bit correction method comprising:
comparing a core header, included in a GFP frame with a fixed payload length, with a predetermined expectation value per each bit;
calculating the number of inconsistent bits therebetween; and
outputting the predetermined expectation value instead of the core header when the number of inconsistent bits is equal to or less than n (where n is a natural number).

9. The PLI n-bit correction method according to claim 8, wherein the core header is directly output when the number of inconsistent bits is greater than n.

10. The PLI n-bit correction method according to claim 8, wherein a PLI included in the core header is compared with a PLI expectation value, thus calculating the number of inconsistent bits therebetween.

11. The PLI n-bit correction method according to claim 8, wherein the core header and the predetermined expectation value are subjected to exclusive-OR operation per each bit and then added together, thus calculating the number of inconsistent bits therebetween.

12. The PLI n-bit correction method according to claim 8, wherein a first expectation value and a second expectation value are used as the predetermined expectation value, wherein a first number of inconsistent bits is calculated based on the first expectation value whilst a second number of inconsistent bits is calculated based on the second expectation value, and wherein the minimum number of inconsistent bits, which is either the first or second number of inconsistent bits, is defined as m, which satisfies a condition of n<m/2.

13. A GFP frame transfer method comprising:
extracting a core header from a GFP frame with a fixed payload length;
comparing the core header with a predetermined expectation value for each bit;
calculating the number of inconsistent bits therebetween;
outputting the predetermined expectation value instead of the core header when the number of inconsistent bits is equal to or less than n (where n is a natural number) or directly outputting the core header when the number of inconsistent bits is greater than n;
generating a Layer 2 synchronization signal indicating establishment of Layer 2 synchronization when errorless core headers are consecutively output two times or an event of Layer 2 desynchronization when the number of inconsistent bits exceeds n so that the core header is directly output without error correction; and
performing predetermined processing on a payload of the GFP frame dropping the core header when the Layer 2 synchronization signal indicates establishment of Layer 2 synchronization or discarding the GPF frame without performing predetermined processing on the payload when the Layer 2 synchronization signal indicates the event of Layer 2 desynchronization.

14. The PLI n-bit correction circuit according to claim 2, wherein a PLI included in the core header is compared with a PLI expectation value, thus calculating the number of inconsistent bits therebetween.

15. The PLI n-bit correction circuit according to claim 2, wherein the core header and the predetermined expectation value are subjected to exclusive-OR operation for each bit and then added together, thus calculating the number of inconsistent bits therebetween.

16. The PLI n-bit correction circuit according to claim 2, wherein a first expectation value and a second expectation value are used as the predetermined expectation value, wherein a first number of inconsistent bits is calculated based on the first expectation value whilst a second number of inconsistent bits is calculated based on the second expectation value, and wherein the minimum number of inconsistent bits, which is either the first or second number of inconsistent bits, is defined as m, which satisfies a condition of n<m/2.

17. The PLI n-bit correction method according to claim 9, wherein a PLI included in the core header is compared with a PLI expectation value, thus calculating the number of inconsistent bits therebetween.

18. The PLI n-bit correction method according to claim 9, wherein the core header and the predetermined expectation value are subjected to exclusive-OR operation per each bit and then added together, thus calculating the number of inconsistent bits therebetween.

19. The PLI n-bit correction method according to claim 9, wherein a first expectation value and a second expectation value are used as the predetermined expectation value, wherein a first number of inconsistent bits is calculated based on the first expectation value whilst a second number of inconsistent bits is calculated based on the second expectation value, and wherein the minimum number of inconsistent bits, which is either the first or second number of inconsistent bits, is defined as m, which satisfies a condition of n<m/2.
